(19) United States
(12) Patent Application Publication
(10) Pub. No.: US 2010/0186806 A1
(43) Pub. Date: Jul. 29, 2010

(54) PHOTOVOLTAIC MODULE

(75) Inventors: Hiroaki Morikawa, Tokyo (JP); Naoki Ito, Tokyo (JP); Kaoru Okaniwa, Ibaraki (JP); Michiaki Yajima, Ibaraki (JP); Takayuki Suzuki, Ibaraki (JP)

Correspondence Address: BUCHANAN, INGERSOLL & ROONEY PC, POST OFFICE BOX 1404, ALEXANDRIA, VA, 22313-1404, US

(73) Assignee: Mitsubishi Electric Corporation, Chiyoda-ku (JP)

(21) Appl. No.: 12/359,774

(22) Filed: Jan. 26, 2009

(51) Int. Cl. H01L 31/00

(52) U.S. Cl. 136/256

(57) ABSTRACT

A solar cell has a non-light-receiving side and a light-receiving side that faces a backside of an optically-transparent cover plate. A heatsink has a backside that faces the non-light-receiving side of the solar cell. The heatsink is formed of a graphite-containing material having a concave and convex texture as a radiating fin.

### BACKGROUND OF THE INVENTION

1. Field of the Invention

The present invention relates to a photovoltaic module including a heatsink for suppressing a temperature rise.

2. Description of the Related Art

In general, a silicon crystal solar cell shows a degradation of power generation efficiency as the temperature of the solar cell rises. The voltage of the solar cell (represented by the open-circuit voltage (Voc)) is particularly influenced by the temperature rise. In the case of a polycrystalline cell, the voltage decreases at a rate of about −0.4%/° C. As a result, the maximum output (Pm) of the solar cell decreases at a rate of about −0.5%/° C. In midsummer, the cell temperature is considered to rise to about 70° C. to 80° C. At the cell temperature of 70° C., for example, the output of the solar cell is lowered to 78% of the output of the cell at the cell temperature of 25° C. that is the reference state defined in Japanese Industrial Standards (JIS), which is not negligible. For this reason, the total power generation in summer with large amount of solar radiation and long hours of daylight is not much more than that in winter with short hours of daylight, and the total power generation is largest in spring and autumn in a year. In addition, when leaves are fallen on a module including a number of cells connected in series to each other and the fallen leaves cover a cell, for example, the electric power of the module is entirely concentrated on the covered cell, resulting in heat generation of the cell. This kind of phenomenon is called a hot spot in which the generated heat may damage the module. In this case, the heat dissipation is a useful means for overcoming the heat problem.

Examples of conventional heat dissipation methods include a method in which fins are provided on the backside of a photovoltaic (PV) module, a method using a hybrid module in which solar cells are cooled with a heat medium such as water and, at the same time, warm water produced by the heat is utilized and a heatsink, a method in which a fluid as a heating medium is filled in the backside of the module, and a method in which water cooling, air cooling, cooling with a heatsink sheet, cooling with a heat pipe, or the like is adopted for cooling the module (see, for example, Japanese Patent Application Laid-open No. H11-36540, Japanese Patent Application Laid-open No. H10-62017, Japanese Patent Application Laid-open No. 2005-123452, Japanese Patent Application Laid-open No. H11-354819, Japanese Patent Application Laid-open No. 2005-18352, Japanese Patent Application Laid-open No. 2002-170974, Japanese Patent Application Laid-open No. 2005-136236, and Japanese Patent Application Laid-open No. H9-186353)

However, because the above heat dissipation methods disadvantageously incur an increase in cost of the module, what happens now is that any particularly measure for heat dissipation is not taken in actual PV modules.

### SUMMARY OF THE INVENTION

It is an object of the present invention to at least partially solve the problems in the conventional technology.

According to one aspect of the present invention, there is provided a photovoltaic module including an optically-transparent cover plate; a solar cell having a non-light-receiving side and a light-receiving side that faces a backside of the optically-transparent cover plate; and a heatsink having a backside that faces the non-light-receiving side of the solar cell. The heatsink is formed of a graphite-containing material having a concave and convex texture as a radiating fin.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic diagram illustrating a partial structure of a PV module according to an embodiment of the present invention;

FIG. 2 is a cross section of the PV module shown in FIG. 1;

FIG. 3 is a graph showing results of outdoor evaluation (backside temperatures) of a PV module according to an Example 1 and a PV module according to a Comparative Example 1 which have been measured outdoors;

FIG. 4 is a graph showing results of outdoor evaluation (open circuit voltage) of the PV module according to the Example 1 and the PV module according to the Comparative Example 1; and

FIG. 5 is a schematic diagram of a concave and convex cross sectional shape of a heatsink used in the Example 1.

### DETAILED DESCRIPTION OF THE PREFERRED EMBODIMENTS

Exemplary embodiments of a photovoltaic module according to the present invention are explained in detail below with reference to the accompanying drawings.

The production of the heatsink using a mixture of a graphite powder with a resin is preferred, because a fin structure with concaves and convexes formed therein can easily be produced, for example, by press molding, and the obtained heatsink is lightweight with excellent heat radiation characteristics. Such graphite powders include, for example, powdered products of natural graphite such as flaky natural graphite from China, Madagascar, Ukraine, and Brazil, natural flaky graphite from Sri Lanka, and earthy natural graphite from North Korea, China, South Korea, and Mexico, powdered products of artificial graphite, and powders produced by pulverizing expanded graphite or pulverizing sheets of expanded graphite. In particular, the use of natural graphite powders is preferred from the viewpoint of reducing the cost, and the use of expanded graphite powders is preferred from the viewpoint of improving the thermal conductivity. The shape of the graphite powders is not particularly limited and may be, for example, spherical, massive, flaky, or dendritic. On the other hand, the average particle diameter of the graphite powder is preferably 5 micrometers to 500 micrometers, and more preferably, 10 micrometers to 300 micrometers. When the average particle diameter is smaller than 5 micrometers, the moldability of the graphite-containing material is likely to be degraded. On the other hand, when the average particle diameter is larger than 500 micrometers, the production of a dense molded product is likely to become difficult.

For example, thermoplastic resins and heat-curable resins may be used as the resin to be mixed with the graphite powder.

Examples of thermoplastic resins include polyethylenes, polypropylenes, polymethyl pentenes, polybutenes, crystalline polybutadiene polystyrenes, polybutadienes, styrene butadiene resins, polyvinyl chlorides, polyvinyl acetates, polyvinylidene chlorides, ethylene vinyl acetate copolymers (EVAs, ASs, ABSs, ionomers, AASs, and ACSs), polymethyl methacrylates(acrylic resins), polytetrafluoroethylenes, ethylene polytetrafluoroethylene copolymers, polyacetals(polyoxymethylenes), polyamides, polycarbonates, polyphenylene ethers, polyethylene terephthalates, polybutylene terephthalates, polyarylates (U polymers), polystyrenes, polyether sulfones, polyimides, polyamide imides, polyphenylene sulfides, polyoxybenzoyls, polyether ether ketones, polyether imides, and other liquid crystal polyesters.

Examples of heat-curable resins include phenolic resins, amino resins (urea resins, melamine resins, and benzoguanamine resins), unsaturated polyester resins, diallyl phthalate resins, alkyd resins, epoxy resins, urethane resins, and silicone resins.

The resin is preferably to be a heat-curable resin, particularly, a phenolic resin or an epoxy resin, from the viewpoint of excellent handleability and weathering resistance.

The mixing ratio between the graphite powder and the resin is such that the amount of the graphite powder is preferably 30 parts by weight to 95 parts by weight, and more preferably, 40 parts by weight to 90 parts by weight, based on 100 parts by weight of the total amount of the graphite powder and the resin.

The heatsink may be produced by any manufacturing process without particular limitation. For example, a heatsink, which is formed of a graphite-containing material, for example, a material containing a graphite powder and a resin component, and has concaves and convexes in its desired sites, can be produced by molding. Specifically, the heatsink may be produced by subjecting a graphite-containing material such as a mixture of a graphite powder with a resin to agitation, mixing, kneading, rolling and the like by a kneader, a mixing-grinding machine, a Henschel mixer, a planetary mixer, or a rolling mill, and molding the resultant mixture by a conventional plastic molding method such as injection molding, extrusion, or pressing.

The concave and convex texture functions as radiating fins, and a conventionally known shape can be taken as the shape of the fins. Example of shapes of the convexes, which function as fins, include linear fins, curved fins or bent fins (square, rectangular, triangular, trapezoidal, or other curved surfaces in a section in a direction at a right angle to the longitudinal direction of the fins), annular fins (rectangular, triangular, trapezoidal, or other curved surfaces in a section in a radial direction), and projected fins (columnar, conical, polygonal pyramidal or other shapes).

The thickness of the heatsink and the size of the concaves and convexes are not particularly limited. In general, however, the thickness of the flat plate part including the basal part of the convexes is preferably 0.5 millimeter to 10 millimeters, and more preferably, 1 millimeter to 5 millimeters.

An optically-transparent cover plate may be an optically-transparent flat substrate, or alternatively may be a collecting lens for collecting sunlight on the light-receiving side of a solar cell. Materials for the optically-transparent cover plate include, for example, synthetic resins such as transparent glasses, transparent acrylic resins, and transparent polycarbonate resins. The thickness of the optically-transparent substrate is generally 1 millimeter to 10 millimeters, and preferably 2 millimeters to 5 millimeters, but is not particularly limited.

Solar cells include, but are not limited to, single crystal silicon substrates, polycrystalline silicon substrates, and amorphous silicon substrates. The size of the solar cell is not particularly limited, and the thickness of the solar cell is generally 160 micrometers to 350 micrometers.

The number of solar cells used in a single PV module may be one. In general, however, two or more solar cells electrically connected to each other are arranged in a planar array.

The solar cell is preferably sealed with a filling member having heat resistance and insulating properties. In this case, an optically-transparent filling member is used at least on the light-receiving side of the solar cell. The filling member used on the non-light-receiving side of the solar cell may not have to optically transparent. For example, the filling member may be a colored material as appropriate. Specific examples of the filling members generally usable include, but are not limited to, ethylene-vinyl acetate copolymers (EVA copolymers).

When the optically-transparent cover plate is an optically-transparent substrate, the solar cell sealed with the filling member is typically sandwiched between the optically-transparent substrate and the heatsink so that the light-receiving side of the solar cell faces the backside of the optically-transparent substrate while the non-light-receiving side of the solar cell faces the backside of the heatsink. When the optically-transparent cover plate is a collecting lens, the solar cell sealed with the filling member is generally arranged at a position where the sunlight is collected on the light-receiving side of the solar cell, in which the solar cell is attached to the heatsink so that the non-light-receiving side of the solar cell faces the backside of the heatsink, and the backside of the collecting lens faces the light-receiving side of the solar cell.

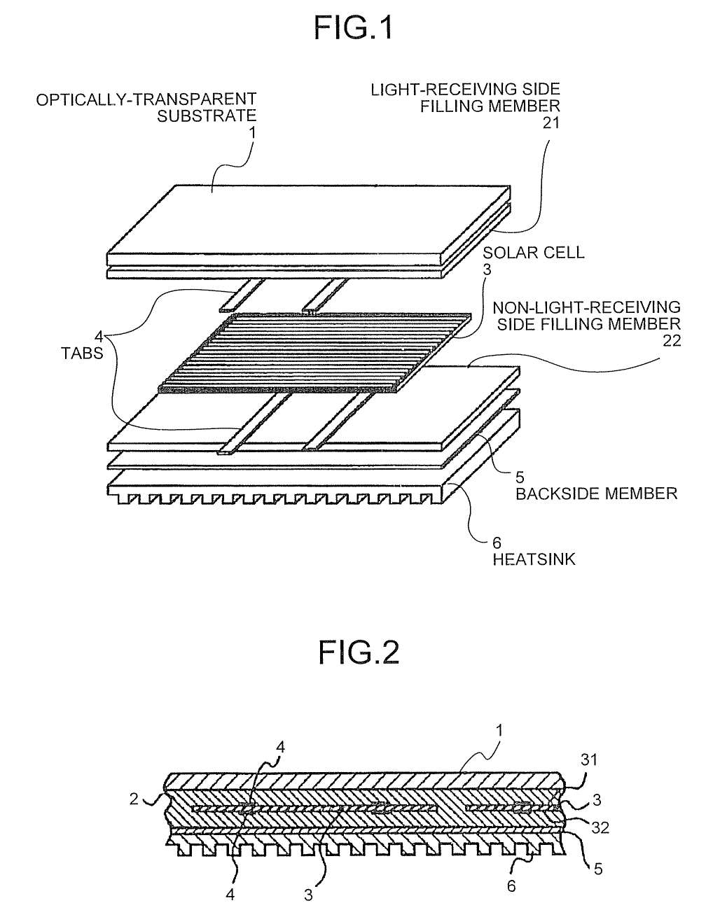

FIG. 1 is a schematic diagram illustrating a partial structure of a PV module according to an embodiment of the present invention, and FIG. 2 is a cross section of the PV module shown in FIG. 1. In the embodiment, a 3-millimeter-thick cover glass (a tempered glass) is used as an optically-transparent substrate 1. A solar cell 3 is arranged such that a light-receiving side 31 faces the backside of the optically-transparent substrate 1 while a non-light-receiving side 32 faces the backside of a heatsink 6 formed of a graphite material. The heatsink 6 has a number of convexes and concaves (fins) on its surface. Generally, a plurality of solar cells 3 are generally arranged in a planar form being connected in series to each other through a plurality of tabs 4 connected to the upper and lower surfaces (negative electrodes and positive electrodes) of the solar cells 3, although a single solar cell is shown in FIG. 1. A light-receiving side filling member 21 is arranged on the light-receiving side 31 of the solar cell 3, and a non-light-receiving side filling member 22 is arranged on the non-light-receiving side 32 of the solar cell 3. In the embodiment, a sheet-type EVA resin is used as the filling member. A backside member 5 is arranged on the backside of the heatsink 6, that is, on the surface of the heatsink 6 that faces the non-light-receiving side 32. The backside member 5 is optionally provided for preventing, for example, the penetration of moisture into the PV module and is an insulating sheet or plate formed of any material without particular limitation. For example, synthetic resin sheets or synthetic resin sheet-type plates having a single-layer or multilayer structure, for example, a laminate film including a Tedlar film (polyvinylidene fluoride (PVF)) manufactured by E.I. de Pont de Nemours&CO. and PET (polyethylene terephthalate) may be used. An adhesive can be used for attaching the backside member 5 onto the backside of the heatsink 6. Alternatively, the above filling member is used as the adhesive, and can be attached at the time of manufacturing the PV module.

The PV module according to the present invention may be manufactured by any method without particular limitation. For example, the PV module according to the embodiment shown in FIG. 2 can be manufactured at low cost with high productivity. By heating and pressing processes in manufacturing the PV module, the light-receiving side filling member 21 and the non-light-receiving side filling member 22 are fused to form a filling member 2 for sealing the solar cell 3. The solar cell 3 sealed with the filling member 2 is sandwiched between the backside side of the optically-transparent substrate 1 and the heatsink 6 on its backside with the backside member 5 attached thereon.

In the present invention, a graphite material having a high coefficient of thermal conductivity and a high level of emissivity is used as the material for the heatsink. Furthermore, in the heatsink, concaves and convexes are provided as radiating fins (ribs) for cooling. With this constitution, an excellent heat dissipation effect can be attained, and the temperature of the solar cell can be lowered to such an extent that the power generation efficiency can be satisfactorily improved.

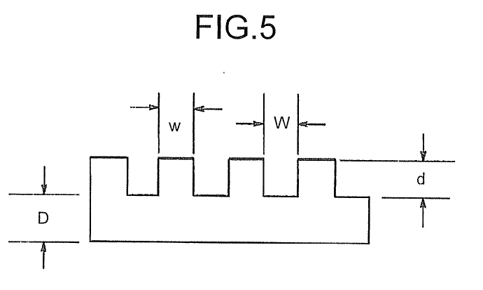

A graphite powder (a pulverized product of an expanded graphite sheet (HGR-207) manufactured by Hitachi Chemical Co., Ltd.; average particle diameter: 200 micrometers) (30 parts by weight) and 70 parts by weight of a resin (a resol-based phenolic resin manufactured by Hitachi Chemical Co., Ltd.) are mixed together by a pressure kneader, and the mixture is press molded by heating and pressing it under conditions with temperature of 170° C. and pressure of 10 MPa for 10 minutes to fabricate a heatsink with a size of 200 millimeters×200 millimeters and having a plurality of concaves and convexes on its one side. The concaves and convexes provided on the surface of the heatsink have a stripe shape in the cross section as shown in FIG. 5. In FIG. 5, the values of W, w, D, and d are 1 millimeter, 1 millimeter, 1 millimeter, and 0.5 millimeter, respectively.

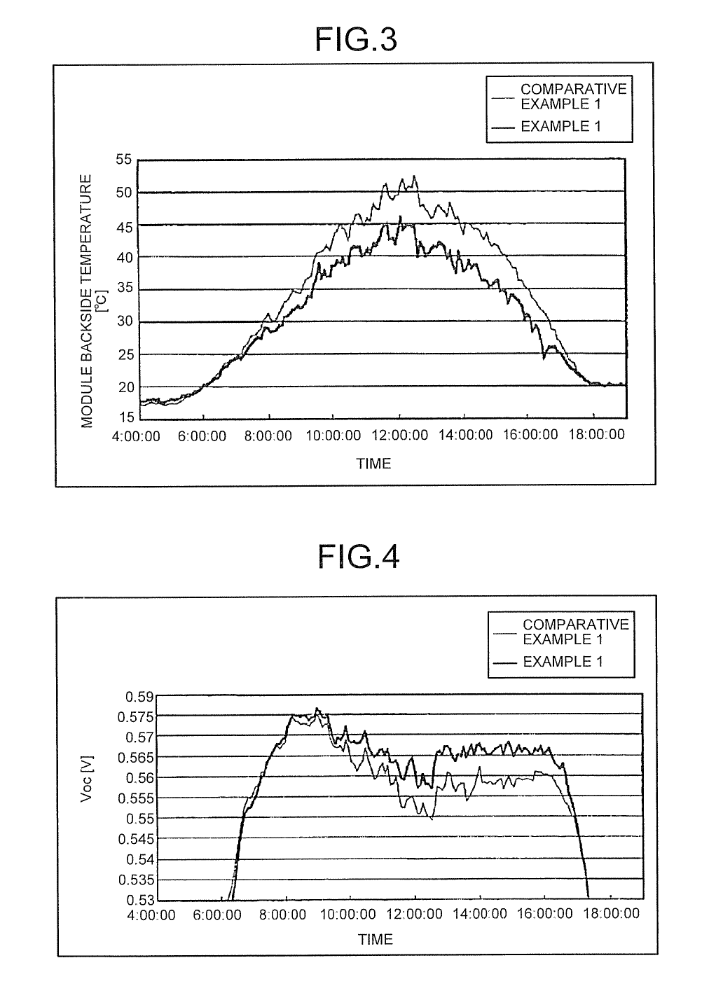

A PV module according to an Example 1 of the embodiment is manufactured as follows. A cover glass having a size of 200 millimeters×200 millimeters×3 millimeters (thickness) is provided as the optically-transparent substrate. An EVA sheet (thickness: 0.6 millimeter) as a filling member on the light-receiving side is placed on the cover glass. A solar cell (polycrystalline silicon, 150 millimeters×150 millimeters×0.25 millimeter) connected so that electricity can be taken out to the outside is placed on the EVA sheet. An EVA sheet (thickness: 0.4 millimeter) as a filling member on the non-light-receiving side, a Tedlar film (thickness: 38 micrometers) as a backside member, an EVA sheet (thickness: 0.4 millimeter) as an adhesive, and the heatsink formed of a graphite-containing material and having concaves and convexes on its one side (outer side) are placed in that order on the solar cell, followed by module sealing with a vacuum laminator to manufacture a PV module. In this case, the module sealing is carried out under conditions with temperature of 150° C., evacuation time of 10 minutes, and pressing time of 15 minutes (pressure: 98 kilopascal). For the PV module thus obtained, the backside temperature and the open circuit voltage (Voc) are evaluated outdoors. The results are shown in FIGS. 3 and 4. The maximum temperature difference, i.e., the difference between the highest backside temperature and the lowest backside temperature, and the maximum open circuit voltage difference, i.e., the difference between the highest open circuit voltage and the lowest open circuit voltage, are shown in Table 1.

A sealed PV module according to a Comparative Example 1 is manufactured in the same manner as in the Example 1, except that a PET sheet (thickness: 85 micrometers) is placed instead of the heatsink used in the Example 1. The PV module thus obtained is evaluated in the same manner as in the Example 1.

TABLE 1

| | | Comparative | |
|---|---|---|---|
| | Example 1 | Example 1 | Difference |
| Temp. (° C.) | 41.3 | 48.0 | 6.7 (maximum |
| | | | temperature |
| | | | difference) |
| Voc (mV) | 566.0 | 557.0 | 9.0 (maximum open |
| | | | circuit voltage |
| | | | difference) |

The values of “temperature” in Table 1 are the backside temperatures when the difference in backside temperature between the Example 1 and the Comparative Example 1 shows the largest value, and the values of “Voc” is the open circuit voltages (Voc) when the difference in open circuit voltage (Voc) between the Example 1 and the Comparative Example 1 shows the largest value.

As described above, according to one aspect of the present invention, a decrease of the power generation efficiency due to a temperature rise in a solar cell can be prevented by applying a heatsink having a concave and convex cross sectional shape as a radiating fin formed of a graphite-containing material to a PV module.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A photovoltaic module comprising:
an optically-transparent cover plate;
a solar cell having a non-light-receiving side and a light-receiving side that faces a backside of the optically-transparent cover plate; and
a heatsink having a backside that faces the non-light-receiving side of the solar cell, wherein
the heatsink is formed of a graphite-containing material having a concave and convex texture as a radiating fin.

2. The photovoltaic module according to claim 1, wherein the graphite-containing material contains a graphite powder and a resin component.

3. The photovoltaic module according to claim 1, wherein the concave and convex texture is formed on a surface of the heatsink.

4. The photovoltaic module according to claim 1, further comprising an insulating backside member attached to the backside of the heatsink.

5. The photovoltaic module according to claim 1, wherein
the optically-transparent cover plate is an optically-transparent substrate, and
the solar cell is sealed by a filling member and sandwiched between the backside of the optically-transparent substrate and the backside of the heatsink.

6. The photovoltaic module according to claim 1, wherein the optically-transparent cover plate is a collecting lens for collecting sunlight on the light-receiving side of the solar cell.

7. The photovoltaic module according to claim 6, wherein the solar cell is sealed by a filling member.

8. The photovoltaic module according to claim 2, wherein an average diameter of particles of the graphite powder is 5 micrometers to 500 micrometers.

9. The photovoltaic module according to claim 8, wherein the average diameter of particles of the graphite powder is 10 micrometers to 300 micrometers.

10. The photovoltaic module according to claim 2, wherein an amount of the graphite powder is 30 parts by weight to 95 parts by weight when a total amount of the graphite powder and the resin is 100 parts by weight.

11. The photovoltaic module according to claim 10, wherein the amount of the graphite powder is 40 parts by weight to parts by weight.
